(19) United States
(12) Patent Application Publication
(10) Pub. No.: US 2002/0061668 A1
(43) Pub. Date: May 23, 2002

(54) Probe card and method of fabricating same

(76) Inventor: Naoyuki Fujimura, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/991,115

(22) Filed: Nov. 16, 2001

(30) Foreign Application Priority Data
Nov. 17, 2000 (JP) 2000-351460

(51) Int. Cl. H05K 1/00

(52) U.S. Cl. 439/83

(57) ABSTRACT

There is provided a probe card for testing a wafer as a whole, wherein parts of probes can be repaired, and adequately secure bonding of the probes with pads is enabled. The probe card for testing a plurality of semiconductor integrated circuits formed on a semiconductor wafer comprises a plurality of the probes for connection with respective testing electrodes of the semiconductor wafer; and wiring board having the pads to be connected with the respective probes. Each of fixed parts where the probes are connected with the respective pads is provided with a hole in order to prevent heat caused by soldering from being conducted to the probes.

### BACKGROUND OF THE INVENTION

1. Field of the Invention

The present invention relates to a probe card for use in conducting a test for electrical continuity, and so forth, on a plurality of semiconductor integrated circuits formed on a semiconductor wafer, in a wafer state, and a method of fabricating the same.

2. Description of the Related Art

Advances in miniaturization of electronic equipment taking place in recent years have been dramatic, and there has been a mounting demand for miniaturization of semiconductor integrated circuits as well, mounted in electronic equipment. In order to cope with such a demand, there has been developed a method of mounting semiconductor integrated circuits in a state as cut-out from a semiconductor wafer, that is, in a bare chip state, directly on a circuit board. For this reason, it is highly desired to supply bare chips of assured quality.

In order to provide quality assurance for bare chips, there is the need for executing burn-in screening of all the semiconductor integrated circuits in a bare chip state. For effective execution of this step of processing, it is required that bare chips en bloc, in a wafer state prior to being cut out, are subjected to the burn-in screening.

In order to execute the burn-in screening of the bare chips en bloc, in the wafer state, it is necessary to simultaneously apply a power source voltage and a signal to a plurality of chips formed on one and the same wafer, thereby activating the plurality of the chips. Accordingly, there is the need for preparing a probe card having not less than several thousand of probes, however, there has been a problem that a conventional needle type probe card can not meet the need in respect of the number of pins and cost as well.

Accordingly, a probe card provided with fine springs formed on a substrate by wire bonding has been disclosed in Japanese Patent Laid-Open No. 10-506197, and Japanese Patent Laid-Open No. 2000-67953. The probes of the probe card described above are formed by shaping a soft metal into a shape by wire bonding, and thereafter, by applying a plating treatment thereto at a time. Consequently, in case that a fault occurs to parts of several thousand of the probes as formed, or a localized fault occurs after repeated usage, it is not possible to repair only faulty parts locally.

To solve the problem as described above, the applicant of the present invention has proposed a probe card as shown in FIG. 4, wherein probes are bonded by solder to pads formed on a wiring board, respectively, in Japanese Patent Application No. 2000-186584.

In FIG. 4, reference numeral 1 denotes the wiring board, reference numeral 2 the pads, reference numeral 3 the probes, reference numeral 3a fixed parts, reference numeral 3b deformed parts, and reference numeral 4 solder patches, and an adequate amount of solder is applied to the respective pads 2 beforehand.

More specifically, with the solder patches 4 in a molten state by applying heat thereto, using heating means (not shown), for example, a laser beam, and so froth, the probes 3, each configured beforehand in a shape having a fixed part 3a and a deformed part 3b, and subsequently, plated with gold for enhancement in the wettability of solder and prevention of oxidation, are held by holding means (not shown), and are caused to descend while controlling the position, tilt, and height thereof, so that the probes 3 are bonded with the pads 2, respectively, by stopping the heating means after checking the position, tilt, and height thereof on top of the respective pads 2.

With such a probe card as described above, however, the temperature of the probes 3 goes up sooner than that of the pads 2 on the wiring board 1 as a result of heating by the heating means because the wiring board 1 is larger in area than the probes 3. Consequently, as shown in FIG. 5, most part of the respective solder patches 4 rise towards the respective fixed parts 3a, and an amount of solder remaining on the respective pads 2 decreases, thereby weakening bonding strength.

It is therefore an object of the invention to provide a suitable strength to bonding of pads with probes in a probe card for use in testing of a wafer as a whole, wherein part of the probes can be repaired.

### SUMMARY OF THE INVENTION

To solve the problem as described above, in accordance with a first aspect of the invention, there is provided a probe card for testing a plurality of semiconductor integrated circuits formed on a semiconductor wafer as shown in, for example, FIG. 1, said probe card comprising a plurality of connection members (for example, probes 3) connected with respective testing electrodes of the semiconductor wafer, and wiring means (for example, a wiring board 1 electrically connected with the plurality of the connection members, wherein the connection members are bonded by soldering to respective junctions (for example, pads 2 formed on the wiring means, and each of fixed parts 3a where the connection members are connected with the respective junctions by soldering is provided with a wettability reducing part (for example, a hole 3c) capable of lowering the wettability of solder used in the soldering.

Herein, the connection member may be any member capable of connecting the wiring means with the plurality of the semiconductor integrated circuits so as to be able to simultaneously apply a power source voltage, signals, and so forth from the wiring means to the respective semiconductor integrated circuits, and examples of the connection member include the probe.

Examples of the wiring means may include the wiring board, and so forth, wherein wiring is provided so as to enable the power source voltage, the signals, and so forth to be conducted to the respective semiconductor integrated circuits.

The junction may be any member having electrical conductivity, and capable of bonding each of the connection members thereto by soldering, and so forth, and examples of the junction include the pad made of a metal.

Since in accordance with the first aspect of the invention, there is provided the probe card comprising the connection members and the wiring means, wherein the connection members are bonded with the respective junctions formed on the wiring means, in case that a fault occurs to parts of the connection members, only the connection members which the fault has occurred can be removed from the junctions corresponding thereto with ease, and new connection members can be connected to the junctions with ease. Accordingly, the connection members to which the fault has occurred can be repaired on a single unit basis without removing all the connection members from the wiring means.

Further, since the respective connection members are provided with the wettability reducing part, and the connection members are bonded by soldering to the respective junctions, the wettability of solder is lowered, so that rising of the solder can be checked, thereby ensuring bonding of the connection members with the respective junctions.

The probe card described above may have a constitution wherein the connection members are formed by shaping a hard metal into a predetermined shape, and applying a plating treatment thereto.

Examples of the hard metal include a metal such as nickel, chromium, iron or an alloy composed thereof as a main constituent.

Further, with the aforementioned probe card, since the connection members are formed by shaping the hard metal into the predetermined shape, and applying the plating treatment thereto, in case of a fault occurring to parts of the connection members, localized repair of only faulty parts thereof can be made in contrast with a case where the connection members are formed by shaping a soft metal such as gold into a predetermined shape by wire bonding, and applying a plating treatment thereto.

The probe card having either of those features described in the foregoing may have a construction wherein the connection members are structured so as to be elastically deformable (having, for example, a deformed part 3b) as shown in, for example, FIG. 1.

With the probe card described above, since the previously described connection members undergo elastic deformation, pressure exerted as a result of the connection members coming into compression contact with the semiconductor integrated circuits can be sufficiently absorbed by the connection members. As a result, absorption of a portion of pressure, higher than necessary, is possible, and the connection members can be in contact with the respective semiconductor integrated circuits at an appropriate pressure.

The probe card described above may have a construction wherein the connection members are configured into a shape substantially resembling the letter S as shown in, for example, FIG. 1.

With the probe card described above, since the connection members are in a shape substantially resembling the letter S, not only the pressure exerted as a result of the compression contact but also a force acting in the direction orthogonal to the direction of the pressure caused by the compression contact can be absorbed satisfactorily.

With the previously described probe card in accordance with the first aspect of the invention may have a constitution wherein the wettability reducing part is a hole (3c) defined in a side face of the fixed part as shown in, for example, FIG. 1.

With the probe card described above, because the hole is provided in the respective connection members, heat which causes solder to melt is dissipated through the hole, thereby preventing conduction of heat to the respective connection members. Accordingly, the wettability of solder is lowered, and rising of the solder can be checked to an adequate degree.

Further, the probe card in accordance with the first aspect of the invention may have a constitution wherein the wettability reducing part is a partially plated part (3d) or a partially coated part (3d), formed on the fixed part as shown in, for example, FIG. 3.

With the probe card described above, rising of solder can be checked to an adequate degree by applying partial plating or partial coating to the fixed part with material capable of lowering the wettability of solder.

In accordance with a second aspect of the invention, there is provided a method of fabricating a probe card for testing a plurality of semiconductor integrated circuits formed on a semiconductor wafer, said method comprising the steps of forming connection members connected with respective testing electrodes of the semiconductor wafer, and bonding the connection members as formed with respective junctions formed on wiring means.

With the aforementioned method of fabricating the probe card comprising the steps of forming the connection members, and bonding the connection members with the respective junctions, the connection members in a state prior to being boned to the wiring means can be formed on a single unit basis, and the connection members as formed can be bonded with the respective junctions on a single unit basis. As a result, parts of the connection members to which a fault occurs can be changed or repaired on a single unit basis.

### BRIEF DESCRIPTION OF THE DRAWINGS

FIG. 1 is a fragmentary perspective view of a first embodiment of a probe card, showing the construction thereof using probes provided with a hole;

FIG. 2 is a sectional view showing the bonding condition of the probe with a pad as shown in FIG. 1;

FIG. 3 is a fragmentary perspective view of a second embodiment of a probe card, showing the construction thereof using probes to which partial plating or partial coating is applied;

FIG. 4 is a fragmentary perspective view of a conventional probe card, showing the construction thereof; and

FIG. 5 is a sectional view showing the bonding condition of the probe with a pad as shown in FIG. 4.

### DESCRIPTION OF THE PREFERRED EMBODIMENTS

Embodiments of the invention are described in detail hereinafter with reference to the accompanying drawings.

First Embodiment

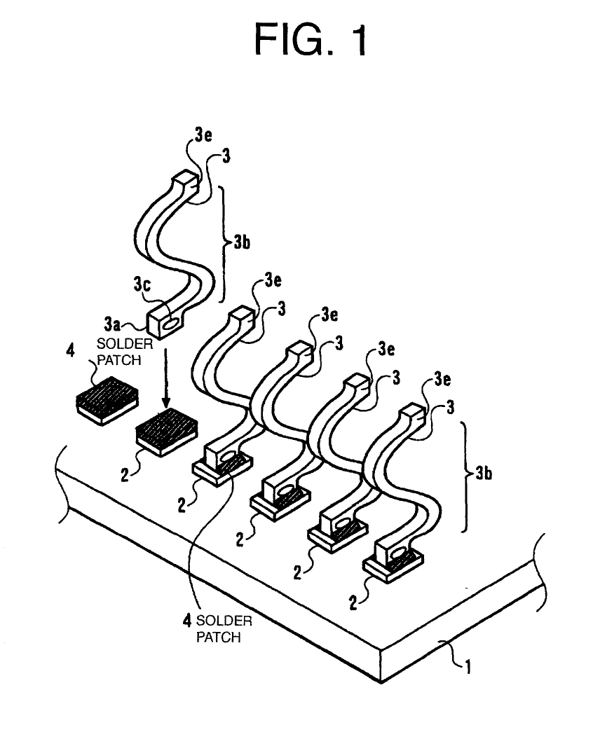

In FIG. 1, reference numeral 1 denotes a wiring board (wiring means), reference numeral 2 pads (junctions), reference numeral 3 probes (contact members), and reference numeral 4 solder patches.

The wiring board 1 comprises a plurality of wires (leads) in order to simultaneously apply a power source voltage, signals, and so forth, for testing electrical continuity, and so forth, of a plurality of semiconductor integrated circuits formed on a semiconductor wafer to these semiconductor integrated circuits. Further, as shown in FIG. 1, a plurality of (for example, several thousand units of) the pads 2 are formed on the surface of the wiring board 1, and the respective wires are connected with the respective pads 2, corresponding thereto, such that the testing described above can be properly conducted.

The pads 2 are connected with the probes 3 described later, respectively, and the surface of the wiring board 1 is coated with a metal layer. Further, the respective pads 2 are formed at positions corresponding to the respective semiconductor integrated circuits so as to enable all the plurality of the semiconductor integrated circuits formed on the semiconductor wafer to be tested with ease.

The probes 3 are in compression contact with respective testing electrodes of the semiconductor wafer, feeding signals, and so forth which are outputted from the wiring board 1 to the respective semiconductor integrated circuits. As shown in FIG. 1, the probes 3 are formed of a hard metal such as nickel, and an alloy thereof, and comprise a fixed part 3a to be bonded with each of the pads 2, a deformed part 3b undergoing deformation when subjected to pressure, and a compression contact part 3e coming in compression contact with the respective semiconductor integrated circuits formed on the semiconductor wafer. The fixed part 3a is configured in a shape having a flat bottom face for easy bonding with each of the pads 2, a sufficient thickness in such a way as to be extended in the downward direction, and a hole (wettability reducing part) 3c defined in a side face thereof. The deformed part 3b is configured in a shape curved so as to substantially resemble the letter S. The compression contact part 3e is configured in a shape having a flat upper face projecting in the upward direction so as to be easily in compression contact with each of the semiconductor integrated circuits.

The probes 3 are finished up by applying a plating treatment with a metal, such as electroplating, and eletroless plating, thereto as a countermeasure for prevention of oxidation thereof and for enhancement in the wettability of solder after the same formed of the hard metal such as nickel and an alloy thereof are configured in the shape described as above.

Because the probes 3 are configured in the shape described as above, and are formed of the hard metal, the probes 3 undergo elastic deformation when subjected to an external force. That is, the probes 3 have elasticity. Since the probes 3 have elasticity, pressure acting in the direction vertical to a contact face when the probes 3 come into compression contact with the semiconductor integrated circuits on the semiconductor wafer is absorbed by the probes 3 undergoing elastic deformation. Accordingly, the probes 3 can be in contact with the semiconductor integrated circuits at an appropriate pressure after absorbing a portion of the pressure, higher than necessary. Furthermore, since the probes 3 are configured as described above, a force acting in the direction orthogonal to the aforementioned pressure can also be absorbed satisfactorily. As a result, there will occur no misalignment at the contact face between the compression contact part 3e of the probes 3 and the semiconductor integrated circuits.

Next, a method of bonding the probes of a probe card to the pads is described.

First, as shown in FIG. 1, the solder patch 4 in an adequate amount is applied to each of the pads 2 on the wiring board 1, and the solder patch 4 is caused to melt by applying heat using heating means (not shown) such as a laser beam, and so forth, thereto. The probes 3, each finished up separately by shaping the hard metal as described above beforehand, and subsequently, by applying a plating treatment thereto, are held by holding means (not shown), and are caused to descend while controlling the position, tilt, height and so forth, thereof, thereby bringing the probes 3 in contact with the solder patches 4 in a molten state, respectively. By stopping the heating means after checking the position, tilt, and height, and so forth, of the probes 3 on top of the respective pads 2, the probes 3 are bonded to the pads 2, respectively.

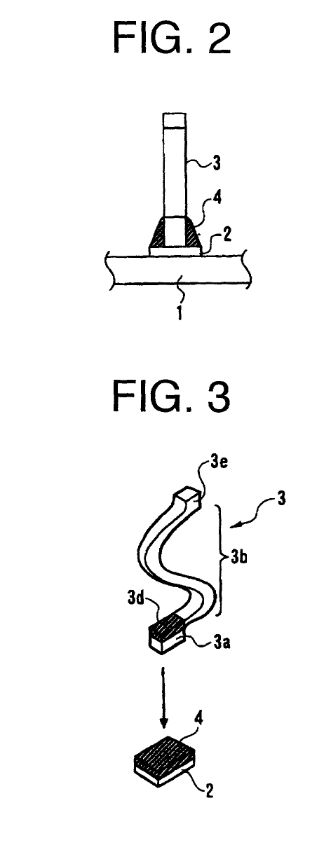

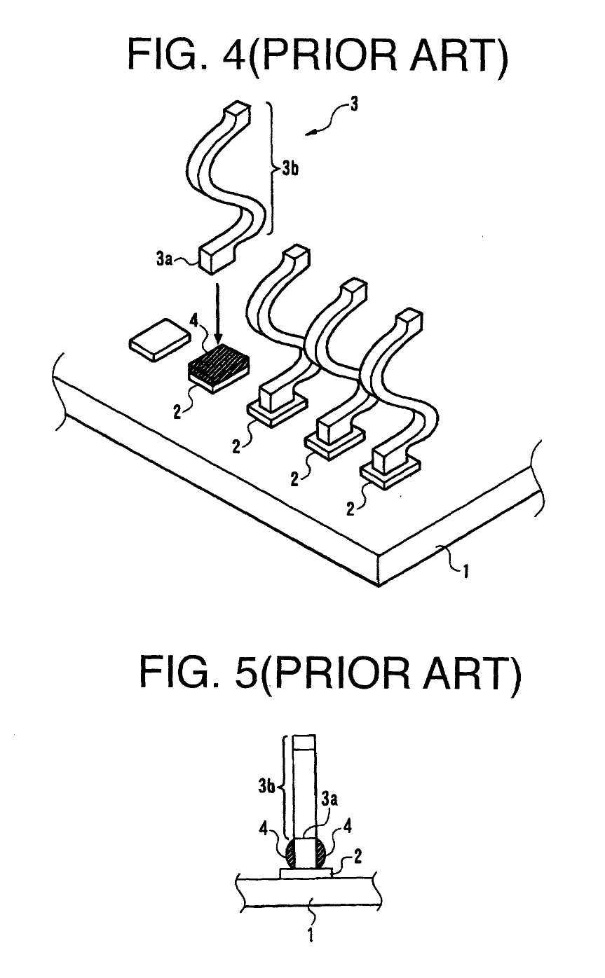

At this point in time, heat is dissipated through the hole 3c defined in the fixed part 3a of the respective probes 3, and thereby conduction of heat towards the upper part of the respective probes 3 is checked. As a result, the wettability of the solder patch 4 is lowered, and as shown in FIG. 2, the solder patch 4 forms a fillet between the fixed part 3a and the pad 2, thus ensuring bonding of the probe 3 to the pad 2.

In this connection, bonding of the probes 3 to the respective pads 2 may be executed by a single unit of the probes 3 or by a plurality of units thereof en bloc.

Second Embodiment

In FIG. 3, reference numeral 1 denotes a wiring board (wiring means), reference numeral 2 a pad (junction), reference numeral 3 a probe (connection member), and reference numeral 4 a solder patches as with the case of the first embodiment.

With a second embodiment of the invention, a partially plated part 3d plated with material such as nickel for lowering the wettability of solder, or a partially coated part 3d coated with the same is formed on top of a fixed part 3a of the probe 3.

More specifically, upon bonding of the probes 3 of a probe card to the respective pads 2, the wettability of the respective solder patches 4 due to thermal melting thereof is lowered by the agency of the partially plated part 3d or the partially coated part 3d, provided on the fixed part 3a of the respective probes 3, so that as with the case of the first embodiment, the solder patch 4 forms a fillet between the fixed part 3a and the pad 2, thus ensuring bonding of the probe 3 with the pad 2.

Thus, because rising of solder towards the probes 3 due to a difference in heat loss coefficient between the probes 3 and the wiring board 1 can be held back to an appropriate level, bonding of the probes 3 to the respective pads 2 can be implemented with reliability.

Further, since the probes 3 are bonded to the respective pads 2 formed on the wiring board 1, in case that a fault occurs to parts of the probes 3 when, for example, the probe card is repeatedly used, only the parts of the probes 3 to which the fault has occurred can be removed from the pads 2 corresponding thereto with ease, and also, newly formed probes 3 can be bonded to the pads 2 with ease. As a result, the faulty parts of the probes 3 can be repaired on the basis of a single unit thereof without removing all the probes 3 from the wiring board 1.

With the aforementioned embodiments of the invention, nickel, an alloy thereof, and so forth are used for the hard metal, however, the scope of the invention is not limited thereto, and other hard metal may be used instead.

Further, nickel is used for forming the partially plated part or the partially coated part, however, partial plating or partial coating may be applied by use of other material capable of lowering the wettability of solder.

It goes without saying that the invention in other respects such as the construction thereof in specific details may be changed as appropriate.

In accordance with a first aspect of the invention, the probe card comprises the connection members and the wiring means, wherein the connection members are bonded with the junctions formed on the wiring means, respectively, so that there is gained an advantage in that in case that a fault occurs to parts of the connection members of the probe card, only the parts of connection members to which the fault has occurred can be removed from the junctions corresponding thereto with ease, and new connection members can be connected to the junctions with ease, thereby enabling any of the connection members to which the fault has occurred to be repaired on a single unit basis without removing all the connection members from the wiring means.

Further, there is gained another advantage in that because the connection members are bonded by soldering to the respective junctions, and the respective connection members are provided with the wettability reducing part for lowering the wettability of the solder patch, rising of solder can be checked, thereby ensuring bonding of the connection members to the respective junctions.

With the probe card having the features as described above, wherein the connection members are formed by shaping the hard metal into the predetermined shape, and applying the plating treatment thereto, there is gained still another advantage in addition to the aforementioned advantages in that even in case of a fault occurring to parts of the connection members, localized repair of only faulty parts of the connection members can be made in contrast with a case where connection members are formed by shaping a soft metal such as gold into a predetermined shape by wire bonding, and applying a plating treatment thereto.

With the probe card having the features as described above, wherein the connection members are structured so as to be elastically deformable, there can be gained a further advantage in addition to the aforementioned advantages in that because a force generated as a result of the connection members coming into compression contact with the semiconductor integrated circuits can be sufficiently absorbed by the connection members, absorption of a portion of the pressure, higher than necessary, is possible, and the connection members can be in contact with the respective semiconductor integrated circuits at an appropriate pressure.

With the probe card described above, wherein the connection members are configured into a shape substantially resembling the letter S, there can be gained a still further advantage in addition to the aforementioned advantages in that a force acting in the direction orthogonal to the direction of the pressure caused by the compression contact can also be absorbed satisfactorily.

With the previously described probe card in accordance with the first aspect of the invention, wherein the wettability reducing part is the hole defined in the side face of the fixed part, since heat which causes solder to melt is dissipated through the hole defined in the respective connection members, unnecessary warming of the upper part of the respective connection members is prevented. As a result, the wettability of the solder patch is lowered, so that there is gained another advantage in that rising of solder can be checked to an adequate degree, thereby ensuring bonding of the connection members with the respective junctions.

Further, with the previously described probe card in accordance with the first aspect of the invention, wherein the wettability reducing part is the partially plated part or partially coated part, formed on the fixed part, rising of solder can be checked to an adequate degree by the effect of the partially plated part or the partially coated part, formed by use of the material capable of lowering the wettability of solder. Thus, there is gained still another advantage of ensuring bonding of the connection members with the respective junctions.

In accordance with a second aspect of the invention, there is provided a method of fabricating the probe card comprising the steps of forming the connection members, and bonding the connection members with the respective junctions whereby the connection members in a state prior to being boned to the wiring means can be formed on a single unit basis, and the connection members as formed can be bonded to the respective junctions on a single unit basis, so that there is gained a further advantage in that parts of the connection members to which a fault occurs can be changed or repaired on a single unit basis.

What is claimed is:

1. A probe card for testing a plurality of semiconductor integrated circuits formed on a semiconductor wafer, said probe card comprising:
a plurality of connection members connected with respective testing electrodes of the semiconductor wafer; and
wiring means electrically connected with the plurality of the connection members, wherein the connection members are bonded by soldering to respective junctions formed on the wiring means, and each of fixed parts where the connection members are connected with the respective junctions by soldering is provided with a wettability reducing part capable of lowering the wettability of solder used in the soldering.

2. A probe card according to claim 1, wherein the connection members are formed by shaping a hard metal into a predetermined shape, and applying a plating treatment thereto.

3. A probe card according to claim 1 or claim 2, wherein the connection members are structured so as to be elastically deformable.

4. A probe card according to claim 3, wherein the connection members are configured into a shape substantially resembling the letter S.

5. A probe card according to claim 1, wherein the wettability reducing part is a hole defined in a side face of the respective fixed parts.

6. A probe card according to claim 1, wherein the wettability reducing part is a partially plated part or a partially coated part, formed on the respective fixed part.

7. A method of fabricating a probe card for testing a plurality of semiconductor integrated circuits formed on a semiconductor wafer, said method comprising the steps of:
forming connection members connected with respective testing electrodes of the semiconductor wafer; and
bonding the connection members as formed with respective junctions formed on wiring means.
